(19) United States
(12) Patent Application Publication
(10) Pub. No.: US 2022/0407024 A1
(43) Pub. Date: Dec. 22, 2022

(54) METHOD FOR PRODUCING A LIGHT-EMITTING DIODE HAVING POLARIZED EMISSION

(71) Applicant: FRAUNHOFER-GESELLISCHAFT ZUR FORDERUNG DER ANGEWANDTEN FORSCHUNG E.V., Munchen (DE)

(72) Inventors: Hendrik Schlicke, Hamburg (DE); Jan Niehaus, Hamburg (DE); Christoph Schloen, Hamburg (DE)

(21) Appl. No.: 17/771,992

(22) PCT Filed: Oct. 28, 2019
(86) PCT No.: PCT/EP2019/079361

§ 371 Date: Apr. 26, 2022

(51) Int. Cl. H01L 51/50; H01L 51/56; H01L 51/52

(52) U.S. Cl. CPC H01L 51/502; H01L 51/56; H01L 51/5293

(57) ABSTRACT

The present invention relates to a method for producing a light-emitting diode having polarized emission, comprising:
applying a liquid, in which elongated semiconductor nanoparticles are dispersed, to a surface of a substrate containing at least two electrodes, and aligning the semiconductor nanoparticles applied on the substrate surface in an electric field generated by the electrodes.
transferring the aligned semiconductor nanoparticles from the surface of the substrate to a surface of a semifinished product of the light-emitting diode.

### FIELD OF THE INVENTION

The present invention relates to a method of producing a light-emitting diode (“LED”) that emits polarized light with a high degree of polarization.

### BACKGROUND

The use of colloidal semiconductor nanoparticles in the field of display technology is known. By varying the shape, size and composition of the semiconductor nanoparticles, it is possible to control the optoelectronic properties thereof. Semiconductor nanoparticles feature a narrow emission spectrum with high quantum yield. The emission can be triggered by optical excitation (photoluminescence) or charge injection (electroluminescence).

A review of semiconductor nanoparticles and the use thereof in display technology can be found in U. Banin et al., Angew. Chem., 2018, 130, p. 4354-4376.

In the case of use of semiconductor nanoparticles for display applications, it is possible to distinguish between two fundamental principles. Firstly, it is possible to exploit the photoluminescence of the semiconductor nanocrystals by exciting them with shorter-wave light. Secondly, the semiconductor nanocrystals (for example as a component in LEDs) can be operated by electroluminescence by the direct conversion of electrical energy to light.

In some current liquid-crystal displays (LCDs), the semiconductor nanoparticles, for example, are a constituent of the background lighting unit. Radiation emitted by an LED (for example a blue LED) induces the semiconductor nanoparticles to photoluminescence. This radiation emitted by the semiconductor nanoparticles and the radiation emitted by the LED can mix, for example, to form a white light which is supplied to the liquid crystal-containing cell.

In “quantum dot” LEDs, the semiconductor nanoparticles are present in the emitter layer between the electrodes and any further functional layers (for example electron transport layers, hole transport layers, hole injection layers, electron injection layers, etc.).

It is possible by means of known synthesis methods (for example wet-chemical methods) to produce semiconductor nanoparticles of defined size and shape. By establishment of suitable synthesis conditions, it is possible to selectively obtain spherical, elongated (e.g. rod-shaped or wire-shaped), platelet-shaped nanoparticles or else nanoparticles having complex geometries with narrow size distribution. It is additionally known that the optoelectronic properties can be influenced in a controlled manner by use of heterostructured semiconductor nanoparticles (for example in the form of a core-shell structure).

Polarized (e.g. linear- or circular-polarized) light plays an important role in many fields of application, for example display technology (e.g. 3-D projection, holography or what are called head-up displays (“HUDs”) in the mobility industry) and science.

Linear-polarized light can be generated, for example, by the filtering of light from an unpolarized-emission light source by means of a linear polarization filter. Although this concept achieves high degrees of polarization, it is inefficient since light having a different polarization plane is first generated and then blocked by the filter. Although lasers emit polarized light, they are unsuitable for surface lighting applications.

More efficient polarized-emission light sources can be obtained when an emitter that emits polarized light is used.

It is known that a layer of aligned elongated semiconductor nanoparticles (especially semiconductor nanorods and semiconductor nanowires, i.e. nanoparticles having an aspect ratio of >1) emits polarized light, either via photoluminescence or alternatively via electroluminescence. One of the challenges that arises in the production of polarized-emission LEDs containing elongated semiconductor nanoparticles is the implementation of high uniformity of alignment of the semiconductor nanoparticles in the emitter layer of the LED. Only when the elongated nanoparticles in the LED emitter layer have high uniformity of alignment does the LED show a high degree of polarization.

R. Hikmet et al., Adv. Mater., 17, 2005, p. 1436-1439, describe the production of a light-emitting diode (LED) with an emitter layer containing nanorods. A liquid in which the semiconductor nanorods are dispersed is applied to a semifinished LED by spin-coating. The semiconductor nanorods are aligned mechanically by levigation of the liquid applied. After completion thereof, the nanorod containing LED has a degree of polarization, determined by electroluminescence spectroscopy, of about 0.25.

A. Rizzo et al., ACS Nano, 2009, 3, p. 1506-1512, likewise describe the production of a light-emitting diode (LED) with a nanorod-containing emitter layer. The semiconductor nanorods are aligned on the surface of a liquid. The nanorods present on the liquid surface are taken up by a stamp and transferred to a semifinished stage of the LED to be produced. After completion thereof, the nanorod-containing LED has a degree of polarization, determined by electroluminescence spectroscopy, of about 0.25.

U.S. Pat. No. 7,700,200 B2 describes an LED with semiconductor nanoparticles present in the emitter layer thereof.

U.S. Pat. No. 10,036,921 B2 describes an emission source for polarized light, wherein aligned nanorods are present in the emission source.

U.S. Pat. No. 9,557,573 B2 describes an apparatus in which there is an arrangement of pixels, and the pixels each contain aligned nanorods.

WO 2015/144288 A1 describes a device for emission of polarized light, wherein the apparatus has a substrate having grooves in which aligned semiconductor nanorods are present. For production of this device, a liquid in which semiconductor nanorods are dispersed is introduced into the grooves of the substrate. After the liquid has evaporated, aligned nanorods are present in the substrate grooves.

US 2019/165291 A1 describes a light-emitting diode with aligned semiconductor nanorods present in the emitter layer thereof. In the process for producing the light-emitting diode, a semifinished diode is first provided. This semifinished diode contains two electrodes. A liquid with the semiconductor nanorods dispersed therein is applied to the semifinished LED. The nanorods are aligned in an electrical field generated by the two electrodes. For the completion, the electrodes that function as anode and cathode in the operation of the LED and further functional layers (e.g. electron and hole transport layers) are added onto the semifinished LED. The finished LED thus has at least four electrodes, with just two of these electrodes being required for the operation of the LED, and the other two electrodes being used exclusively for the alignment of the semiconductor nanorods during the production process. The light-emitting diode thus contains components that are not required for the actual operation of the LED or can even adversely affect operation under some circumstances, and also lead to an unwanted increase in volume of the LED.

### BRIEF DESCRIPTION OF THE DRAWINGS

FIG. 1 shows photoemission spectra of semiconductor nanorods that have been aligned on the substrate by the application of an electrical field to the electrodes.

FIG. 2. shows photoemission spectra of semiconductor nanoparticles in the emitter layer.

### DETAILED DESCRIPTION

It is an object of the present invention to produce a light-emitting diode (LED) via an efficient method. The production method should lead to an LED that can emit polarized light with a high degree of polarization, but the incorporation of components that are not required for the operation of the LED should be avoided as far as possible.

The object is achieved by a method of producing a light-emitting diode having polarized emission, comprising
applying a liquid, in which elongated semiconductor nanoparticles are dispersed, to a surface of a substrate containing at least two electrodes, and aligning the elongated semiconductor nanoparticles applied to the surface of the substrate in an electrical field generated by the electrodes,
transferring the aligned elongated semiconductor nanoparticles from the surface of the substrate to a surface of a semifinished light-emitting diode,
completing the light-emitting diode by mounting one or more components on the semifinished light-emitting diode containing the elongated semiconductor nanoparticles.

In the context of the present invention, the elongated semiconductor nanoparticles are aligned in an electrical field on an external aligner substrate (i.e. one which is not incorporated into the final LED). After alignment thereof in the electrical field, the elongated nanoparticles are removed from the surface of the external substrate in a transfer step and transferred to the surface of a semifinished LED. As will be described in more detail hereinafter, the aligned nanoparticles are transferred from the surface of the substrate first to a surface of an intermediate carrier and from said intermediate carrier to a surface of the semifinished LED (indirect transfer), or alternatively directly from the surface of the substrate to a surface of the semifinished LED. After the components still absent have been mounted on the semifinished LED, the LED is obtained ready for use. It has been found that, surprisingly, nanoparticles aligned on the external substrate in the electrical field can be transferred very efficiently into the semifinished LED by customary transfer methods (for example a thermal release tape or a stamp) while retaining the uniform alignment. Incorporation of components not required for the operation of the LED is avoided in the method of the invention. The method of the invention gives an LED that can emit polarized light with a very high degree of polarization. The polarized light emitted is, for example, a linear-polarized light.

The elongated semiconductor nanoparticles are especially semiconductor nanorods or semiconductor nanowires.

Suitable semiconductor nanorods or nanowires for light-emitting diodes are known to the person skilled in the art.

The semiconductor nanoparticles contain, for example, one or more compound semiconductors and/or one or more elemental semiconductors.

The compound semiconductor is, for example, a II-VI semiconductor, a III-V semiconductor, a I-III-VI semiconductor, a IV-VI semiconductor or a perovskite.

Any of the II-VI, III-V, and IV-VI compound semiconductors may be a binary compound or alternatively also a ternary or quaternary compound.

With regard to the II-VI semiconductor, examples include the following compounds: CdS, CdSe, CdTe, ZnO, ZnS, ZnSe, ZnTe, (Zn,Cd)S, (Zn,Cd)S, (Zn,Cd)Se, (Zn,Cd)Te, Cd(S,Se), Cd(Se,Te), Zn(S,Se), Zn(Se,Te), HgS, HgSe, HgTe, (Hg,Cd)Te.

With regard to the III-V semiconductor, examples include the following compounds: InP, InSb, InAs, GaP, GaAs, GaSb, GaN, AlN, InN, (Al,Ga)As, (In,Ga)N.

With regard to the I-III-VI semiconductor, examples include the following compounds: CuInSe₂, CuInS₂.

With regard to the IV-VI semiconductor, examples include the following compounds: PbS, PbSe, PbTe, SnS, SnSe, SnTe.

Examples of elemental semiconductors include Si, Ge or carbon (for example in the form of “carbon nanorods”).

The semiconductor nanoparticles may contain, for example, just one of the abovementioned semiconductor materials. For controlled adjustment of the optoelectronic properties, it may alternatively be preferable for the semiconductor nanoparticles to have a heterostructure in which a first semiconductor material (for example a first semiconductor compound) and a second semiconductor material (for example a second semiconductor compound) are present. For example, a first semiconductor material is at least partly surrounded by a second semiconductor material (in the form of a rod-in-rod or a dot-in-rod heterostructure). For example, at both ends of an elongated nanoparticle, there is a first semiconductor material, and in between both ends there is a second semiconductor material (for example dumbbell-shaped semiconductor nanowires). Such heterostructures for semiconductor nanorods or nanowires are known to the person skilled in the art; see, for example, U. Banin et al., Angew. Chem., 2018, 130, p. 4354-4376. If the semiconductor nanoparticles are in the form of a heterostructure in which a first semiconductor material is at least partly surrounded by a second semiconductor material, it may be preferable for the second semiconductor material to have a greater bandgap compared to the first semiconductor material.

The elongated semiconductor nanoparticles have, for example, a width in the range from 1 nm to 50 nm, more preferably 2 nm to 30 nm. The aspect ratio (i.e. the ratio of length to width) of the elongated semiconductor nanoparticles is preferably at least 1.25. For the determination of the aspect ratio of an elongated nanoparticle, the width at the “thinnest place” in the nanoparticle is used. The semiconductor nanorods have, for example, a length of ≤200 nm, for example in the range from 5 nm to 200 nm. Nanowires, by comparison with nanorods, have a greater length which may even be in the μm range (for example up to 10 μm). Length and width of the nanorods are determined by means of electron microscopy (for example scanning or transmission electron microscopy).

On account of the elongate form, the light emitted by a single elongated semiconductor nanoparticle has, for example, a degree of polarization, determined by polarization-dependent spectroscopy, of at least 0.3.

Elongated semiconductor nanoparticles are commercially available or can be produced via methods known to the person skilled in the art. The synthesis can be effected, for example, in an organic (preferably high-boiling) or aqueous liquid, or via a gas phase reaction. Information relating to the production of semiconductor nanorods and nanowires can be found, for example, in the following publications:
U. Banin et al., Angew. Chem., 2018, 130, p. 4354-4376;
P. Yang et al., Adv. Mater., 2014, 26, p. 2137-2184.

In order to improve the dispersibility of the semiconductor nanoparticles in the liquid, there may optionally be organic compounds or ligands on the surface of the nanorods. This is known to those skilled in the art.

The liquid in which the semiconductor nanoparticles are dispersed may contain an organic compound. The organic compound is preferably a compound that is liquid at 25° C. The organic compound may, for example, be an aliphatic hydrocarbon, for example an alkane (e.g. a C₅₋₁₂-alkane, more preferably a C₆₋₁₀-alkane) or an alkene; an aromatic compound (e.g. toluene); a halogenated compound; an alcohol; an amine; an ether or an ester or a mixture of at least two of these compounds. If the liquid in which the nanoparticles are dispersed contains a polar organic compound, water may optionally be present. The liquid in which the nanoparticles are dispersed preferably contains less than 5% by volume of water. Even more preferably, the liquid is anhydrous.

The liquid in which nanoparticles are dispersed may also be a melt (e.g. a molten polymer).

The liquid in which the semiconductor nanoparticles are dispersed is applied to a surface of a substrate. As will be described in more detail hereinafter, the substrate contains at least two electrodes that are utilized for the alignment of the nanorods.

The liquid is applied to the substrate surface by methods known to the person skilled in the art. For example, the liquid in which the elongated semiconductor nanoparticles are dispersed is applied by dip coating, spin coating, spray coating or drop coating.

The substrate is, for example, a plastic substrate, a glass substrate, an oxidized silicon wafer or a ceramic substrate. It is alternatively possible to use other materials capable of electrically insulating the electrodes from one another.

Electrodes of the substrate are preferably arranged such that, after application of a voltage and formation of an electrical field, a high proportion of the field runs parallel to the substrate surface to which the nanorod-containing liquid is applied. Electrodes suitable for the purpose and relative arrangements of the electrodes to one another are known to the person skilled in the art.

For example, at least one of the electrodes is a branched electrode (i.e. an electrode having branches). It is optionally also possible for both electrodes to be branched. For example, the branched electrode has a shaft from which two or more fingers branch off (also referred to hereinafter as comb electrode). A suitable width of the fingers and suitable distances between the fingers can be determined by routine tests.

In a preferred embodiment, the electrodes are arranged such that there is an interdigitated electrode structure (for example two comb electrodes, with intermeshing fingers). Alternatively, the electrodes may be in a mutually superposed arrangement. The electrodes are arranged such that they do not touch. If the two electrodes are in a superposed arrangement, it is possible, for example, for a first electrode to be present on the surface of the substrate, while the second electrode lying beneath the first electrode is embedded into the substrate; or it is possible, for example, for both electrodes to be embedded into the substrate.

For example, the electrodes (for example in the form of an interdigitated electrode structure) are present on the surface of the substrate. In this case, the electrodes come into contact with the nanoparticle-containing liquid applied.

Alternatively, it is also possible that one electrode is present on the substrate surface and therefore comes into contact with the nanoparticle-containing liquid, while the second electrode is embedded into the substrate and therefore does not come into contact with the liquid. The electrode present on the substrate surface preferably has a branched (e.g. comb-like) structure. The electrode embedded may, for example, be plate-shaped or branched.

In a further illustrative embodiment, the electrodes are embedded into the substrate. Electrodes are preferably fully embedded into the substrate, meaning that the electrodes are beneath the substrate surface and not come into contact with the nanoparticle-containing liquid applied to the substrate surface. However, it is also possible that the electrodes embedded conclude in a planar manner with the substrate surface. The use of embedded electrodes opens up the option of configuring the surface of the substrate to which the nanoparticle-containing liquid is applied as a planar surface. As will be described hereinafter, this can be advantageous when the elongated semiconductor nanoparticles, after they have been aligned in the electrical field, are transferred directly from the surface of the substrate to a semifinished light-emitting diode (i.e. when the transfer is effected by contacting the substrate surface on which the aligned nanoparticles are present with a surface of the semifinished LED and in so doing transferring nanoparticles to the semifinished LED). The electrodes embedded into the substrate may, for example, in each case have a branched (e.g. comb-like) structure and hence be arranged relative to one another such that there is an interdigitated electrode structure. Alternatively, it is also possible that the embedded electrodes take the form of an upper electrode and a lower electrode, with the upper electrode closer to the substrate surface compared to the lower electrode. The upper electrode, i.e. the one closer to the substrate surface, is, for example, a branched (e.g. comb-like) electrode, and the lower electrode is, for example, a plate-shaped or likewise a branched (e.g. comb-like) electrode.

Suitable materials for the formation of electrodes are known to the person skilled in the art. For example, the electrodes of the substrate contain a precious metal (e.g. platinum, palladium, gold or silver), copper, titanium, aluminum, indium tin oxide, fluorine-doped tin oxide (“FTO”) or carbon (e.g. graphite, graphene, carbon nanotubes, carbon nanoparticles).

Applying an electrical voltage to the electrodes generates an electrical field between the electrodes. The elongated semiconductor nanoparticles become aligned within this electrical field.

The electrical field may be an electrical AC field (generated by AC voltage) or an electrical DC field (generated by DC voltage).

The electrical field is maintained until there is a sufficiently uniform alignment of the elongated semiconductor nanoparticles. For example, the electrical field is maintained until the liquid with which the nanoparticles have been applied to the substrate surface has evaporated essentially completely (for example to an extent of at least 90%, more preferably at least 95%, based on the volume of the liquid). If the liquid is a melt, the molten state is maintained until there is sufficiently uniform alignment of the semiconductor nanoparticles.

Suitable field strengths for the alignment of the elongated semiconductor nanoparticles on the surface of the substrate can be determined by the person skilled in the art by routine tests.

The alignment of the nanoparticles in the electrical field can optionally be verified by recording photoluminescence spectra and the degree of polarization determined from the spectra.

The aligned semiconductor nanoparticles are transferred from the surface of the substrate to a semifinished light-emitting diode.

The transfer removes the aligned semiconductor nanoparticles from the surface of the substrate and transfers them to a surface of the semifinished LED.

The transfer may be an indirect transfer or a direct transfer. In the case of indirect transfer, the elongated semiconductor nanoparticles aligned by the electrical field are transferred from the surface of the substrate to a surface of an intermediate carrier and then from the surface of the intermediate carrier to a surface of the semifinished LED. In the case of direct transfer, the elongated semiconductor nanoparticles aligned by the electrical field are transferred directly from the surface of the substrate (i.e. without use of an intermediate carrier) to a surface of the semifinished LED.

The indirect transfer variant typically comprises the following steps:

(i) a surface of the intermediate carrier is contacted with the aligned semiconductor nanoparticles present on the substrate surface,
(ii) the intermediate carrier is removed from the substrate, with the semiconductor nanoparticles remaining at least partly on the surface of the intermediate carrier,
(iii) the surface of the intermediate carrier on which the nanoparticles are present is contacted with a surface of the semifinished LED,
(iv) the intermediate carrier is removed from the semifinished LED, with the semiconductor nanoparticles remaining at least partly on the surface of the semifinished LED.

Suitable intermediate carriers for indirect transfer are known to the person skilled in the art. For example, the intermediate carrier is a stamp, a thermally detachable adhesive tape (also referred to as thermal release tape) or a polymer film.

The contact surface of the stamp is manufactured, for example, from an elastomer, for example a polysiloxane such as PDMS (elastomer stamp). Such stamps for the transfer of the material from a first surface to a target surface are known to the person skilled in the art.

By varying the contact pressure, the temperature and/or the angle at which the transfer is conducted, it is possible to optimize the transfer step. Suitable parameters can be determined by the person skilled in the art by routine tests.

A thermally detachable adhesive tape shows strong adhesion at room temperature and can be detached again by heating on completion of transfer. Such thermally detachable adhesive tapes are commercially available.

Indirect transfer can also be effected, for example, in that a polymer film (for example a film of a polyacrylate, polymethylacrylate or polymethylmethacrylate, or a film of a natural polymer such as cellulose or cellulose acetate) is formed on the aligned nanoparticles present on the substrate surface, the polymer film together with the adhering nanoparticles is removed from the substrate surface and then is contacted with a surface of the semifinished LED, and the nanoparticles remain on the surface of the semifinished LED when the polymer film is removed.

In direct transfer, for example, the surface of the substrate on which the aligned nanoparticles are present is contacted with the surface of the semifinished LED, and then the substrate is removed from the semifinished LED, with the semiconductor nanoparticles remaining at least partly on the surface of the semifinished LED. By variation of the contact pressure, the temperature and/or the angle at which the transfer is conducted, it is possible to optimize the transfer step. Suitable parameters can be determined by the person skilled in the art by routine tests. In direct transfer of the aligned nanoparticles from the substrate surface to a surface of the semifinished LED, no intermediate carrier is required.

In a further illustrative variant of direct transfer, multiple layers are applied to the aligned semiconductor nanoparticles present on the surface of the substrate, with these layers forming the semifinished light-emitting diode, and then the substrate is removed from the semifinished LED, with the aligned semiconductor nanoparticles remaining at least partly on the surface of the semifinished light-emitting diode.

A semifinished LED is understood to mean a device that already contains components of the LED, but one or more components still have to be added thereto in order to obtain an LED ready for operation.

For example, the semifinished LED contains one or more of the following LED components: an electron transport layer (ETL), a hole transport layer (HTL), an electron injection layer (EIL), a hole injection layer (HIL), a cathode, an anode.

Suitable materials for these components of a light-emitting diode are known to the person skilled in the art. For example, reference may be made to the materials specified in US 2019/165291 A1 (paragraphs [0083]-[0088]).

The hole transport layer and/or the hole injection layer may contain, for example, one or more of the following compounds: poly(3,4-ethylenedioxythiophene) polystyrenesulfonate (PEDOT/PSS), polythiophene, polyanilines, tri[4-(5-phenyl-2-thienyl)phenyl]amine, 4,4′,4″-tri[2-naphthyl(phenylamino)]triphenylamine (2-TNATA), 4,4′,4″-tri(3-methylphenylanilino)triphenylamine (m-MTDATA), Cu-phthalocyanine (CuPc), N,N′-diphenyl-N,N′-bis(3-methylphenyl)-1,1′-diphenyl-4,4′-diamine (TPD), a molybdenum oxide, a vanadium oxide, a tungsten oxide, a chromium oxide, a molybdenum sulfide, a tungsten sulfide, a molybdenum selenide, a tungsten selenide, a graphene oxide, a polyvinylcarbazole or a polytriphenylamine.

The electron transport layer contains, for example, an inorganic oxide, for example a zinc oxide, a titanium oxide, a tin oxide, a zirconium oxide, a tantalum oxide, an Al—Zn oxide, a Zn—Sn oxide or an In—Sn oxide, or an organic compound, for example aluminum tris(8-hydroxyquinoline).

The electron injection layer contains, for example, one or more of the following compounds: LiF, lithium-(8-hydroxyquinoline), an alkali metal oxide (e.g. a lithium oxide or a lithium boroxide), an alkali metal silicate, an alkali metal carbonate, an alkali metal fluoride.

For example, the transferred semiconductor nanoparticles are present on the electron transport layer (ETL) or the hole transport layer (HTL) of the semifinished LED.

The aligned semiconductor nanoparticles transferred into the semifinished LED function in the final LED as electroluminescent emitter layer that emits polarized light. On account of the very uniform alignment of the elongated nanoparticles, the emitted polarized light has a very high degree of polarization.

After the semiconductor nanoparticles have been transferred, the missing LED components are added onto the semifinished nano particle-containing product. The components still to be added on may, for example, be one or more of the following components if these were not already present in the semifinished LED before the nanoparticle transfer: an electron transport layer (ETL), a hole transport layer (HTL), an electron injection layer (EIL), a hole injection layer (HIL), a cathode, an anode.

Since the elongated semiconductor nanoparticles, after they have been aligned in the electrical field on the surface of the substrate, are transferred from the substrate surface to a surface of a semifinished LED, the method of the invention affords an LED in which the aligner substrate is no longer present.

In an illustrative embodiment, the semifinished LED contains at least a hole transport layer and an anode and optionally a hole injection layer, the transferred semiconductor nanoparticles are present on the hole transport layer, and the components still to be added on after the transfer include at least an electron transport layer and a cathode and optionally an electron injection layer. In a further illustrative embodiment, the semifinished LED contains at least an electron transport layer and a cathode and optionally an electron injection layer, the transferred semiconductor nanoparticles are present on the electron transport layer, and the components still to be added on after the transfer include at least a hole transport layer and an anode, and optionally a hole injection layer.

The present invention also relates to a light-emitting diode comprising an emitter layer in which elongated semiconductor nanoparticles are present, wherein the light emitted by the elongated semiconductor nanoparticles via electroluminescence has a degree of polarization, determined by polarization-dependent spectroscopy, of at least 0.35.

The polarized light is preferably a linear-polarized light.

The degree of polarization PG is found from the following relationship:

PG=(I_{∥}−I_{⊥})/(I_{∥}+I_{⊥})
where
I_{∥}: total intensity of the electroluminescence of the elongated semiconductor nanoparticles in the emitter layer, recorded in parallel polarization direction,
I_{⊥}: total intensity of the electroluminescence of the elongated semiconductor nanoparticles in the emitter layer, recorded in orthogonal polarization direction.

The electroluminescence spectra are recorded at 25° C. The intensity of the peaks is determined from the peak area.

For example, the degree of polarization is 0.35-0.80.

With regard to preferred properties of the elongated semiconductor nanoparticles, reference may be made to the details given above in the description of the method of the invention. Through the selection of suitable ligands present on the surface of the nanoparticles, it is possible to further optimize the alignment characteristics of the elongated nanoparticles.

The LED of the invention contains, as further components, at least two electrodes (cathode and anode). The LED optionally contains one or more of the following components: an electron transport layer (ETL), a hole transport layer (HTL), an electron injection layer (EIL), a hole injection layer (HIL). With regard to suitable materials for these functional layers of a light-emitting diode, reference may be made to the above remarks.

The LED of the invention is preferably an LED obtainable by the above-described process.

The present invention is described in more detail with reference to the example that follows.

### Example

A dispersion of semiconductor nanorods was applied by drop coating to a substrate containing electrodes. The semiconductor nanorods are CdSe/CdS dot-in-rod particles. The nanoparticles were produced by growing an elongated CdS structure onto CdSe nanoparticles. The semiconductor nanorods had a length of (30+/−5) nm and a diameter of (4.4+/−0.8) nm. The substrate was a glass substrate.

The two electrodes (Au/Ti) were comb-shaped and were arranged relative to one another on the surface of the substrate such that there was an interdigitated electrode structure. The height of the electrodes was about 50 nm (about 40 nm of Au on about 10 nm of Ti bonding layer).

After the application, the electrodes were first fully covered by the liquid. An electrical AC field was applied to the electrodes (amplitude: 5-7.5 V/μm). After the liquid had evaporated, the field was removed.

As a result of the application of the electrical field, the semiconductor nanorods were aligned on the substrate.

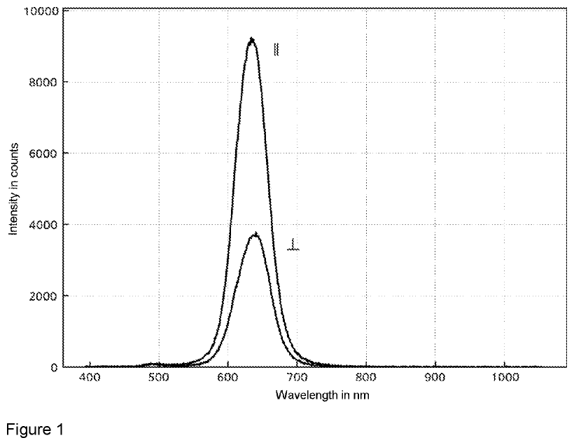

FIG. 1 shows photoemission spectra of semiconductor nanorods that have been aligned on the substrate by the application of an electrical field to the electrodes. The spectra were recorded under excitation with blue light (˜450 nm) in parallel and orthogonal polarization direction. A degree of polarization PG of 0.4 was ascertained from the photoemission spectra.

Using a thermally detachable adhesive tape that functions as an intermediate carrier, a layer of the aligned semiconductor nanorods was removed from the surface of the substrate.

Thereafter, the nanoparticle layer removed from the aligner substrate was transferred to the surface of a semifinished LED. For this purpose, the layer of the semiconductor nanorods adhering to the thermally detachable adhesive tape was contacted with the upper layer of the semifinished LED. As a result of heating to 150° C., the nanoparticle layer became detached from the thermally detachable adhesive tape, and the tape was removed. The upper layer of the semifinished LED was a hole transport layer (HTL) that contained polyvinylcarbazole. The semifinished LED also contained an indium tin oxide electrode present on a glass substrate and a hole injection layer (HIL). The hole injection layer contained poly(3,4-ethylenedioxythiophene) polystyrenesulfonate (PEDOT:PSS).

On completion of transfer of the nanorods, the components still missing for completion of an LED ready for operation were added on. For this purpose, ZnO nanoparticles as electron transport layer and an aluminum cathode (thickness about 200 nm) were applied to the semifinished LED containing the aligned nanorods.

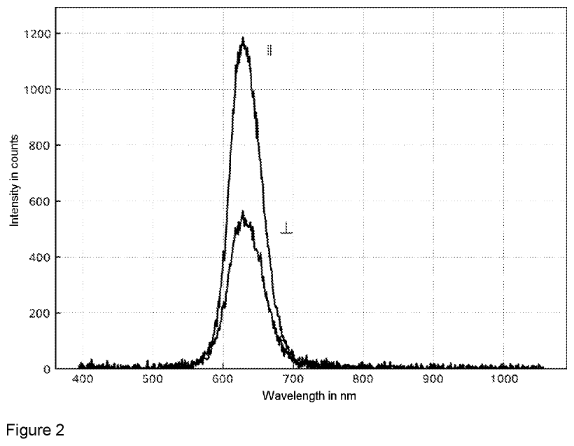

In the final LED, the aligned semiconductor nanorods function as emitter layer. For the determination of the degree of polarization, the total intensity of electroluminescence of the elongated semiconductor nanoparticles in the emitter layer, recorded in parallel polarization direction, and the total intensity of electroluminescence of the elongated semiconductor nanoparticles in the emitter layer, recorded in orthogonal polarization direction, were measured. The degree of polarization PG=(I_{∥}−I_{⊥})/(I_{∥}+I_{⊥}) was 0.4. The spectra measured are shown in FIG. 2. The method of the invention thus affords an LED having a very high degree of polarization in operation. Since the elongated semiconductor nanoparticles, after they have been aligned in the electrical field on the surface of the substrate, have been transferred from the substrate surface to a surface of a semifinished LED, the method of the invention affords an LED in which the aligner substrate is no longer present. The incorporation of a component which is not required for the operation of the LED is thus avoided.

1. A method of producing a light-emitting diode having polarized emission, comprising:
applying a liquid, in which elongated semiconductor nanoparticles are dispersed, to a surface of a substrate containing at least two electrodes, and aligning the elongated semiconductor nanoparticles applied to the surface of the substrate in an electrical field generated by the electrodes;
transferring the aligned elongated semiconductor nanoparticles from the surface of the substrate to a surface of a semifinished light-emitting diode; and
completing the light-emitting diode by mounting one or more components on the semifinished light-emitting diode containing the elongated semiconductor nanoparticles.

2. The method of claim 1, wherein the elongated semiconductor nanoparticles are semiconductor nanorods or semiconductor nanowires.

3. The method of claim 1, wherein the electrodes are present on the surface of the substrate.

4. The method of claim 1, wherein at least one of the electrodes is embedded into the substrate.

5. The method of claim 1, wherein the electrodes are branched and form an interdigitated electrode arrangement.

6. The method of claim 1, wherein the electrodes are in a mutually superposed arrangement.

7. The method of claim 1, wherein the electrical field is an electrical alternating field.

8. The method of claim 1, wherein the transfer comprises transferring the aligned elongated semiconductor nanoparticles from the surface of the substrate to a surface of an intermediate carrier and then from the surface of the intermediate carrier to the surface of the semifinished light-emitting diode.

9. The method as claimed in claim 8, wherein the intermediate carrier is a stamp, a heat-detachable adhesive tape or a polymer film.

10. The method of claim 1, wherein the transfer comprises contacting the surface of the substrate on which the aligned elongated semiconductor nanoparticles are present with the surface of the semifinished light-emitting diode and then removing the substrate from the semifinished light-emitting diode, with the elongated semiconductor nanoparticles remaining at least partly on the surface of the semifinished light-emitting diode.

11. The method of claim 1, wherein the transfer comprises applying multiple layers to the aligned elongated semiconductor nanoparticles present on the surface of the substrate, where these layers form the semifinished light-emitting diode, and then removing the substrate from the semifinished light-emitting diode, with the elongated semiconductor nanoparticles remaining at least partly on the surface of the semifinished light-emitting diode.

12. A light-emitting diode comprising an emitter layer in which there are elongated semiconductor nanoparticles, wherein light emitted by the elongated semiconductor nanoparticles has a degree of polarization, determined by polarization-dependent spectroscopy, of at least 0.35.

13. A light-emitting diode obtained by the method of claim 1.

14. The light emitting diode of claim 13, comprising an emitter layer in which there are elongated semiconductor nanoparticles, wherein light emitted by the elongated semiconductor nanoparticles has a degree of polarization, determined by polarization-dependent spectroscopy, of at least 0.35
